(19) United States
(12) Patent Application Publication
(10) Pub. No.: US 2014/0076523 A1
(43) Pub. Date: Mar. 20, 2014

(54) DEVICES, SYSTEMS, AND METHODS FOR COOLING ELECTRONIC DEVICE HEAT SPREADERS

(71) Applicants: AARON RAY BATKER PRITZKER, GREENFIELD CENTER, NY (US); JOSHUA PATRICK NIXON, SARATOGA SPRINGS, NY (US); JOHN HOWE, SARATOGA SPRINGS, NY (US); ALEXANDER GAILOR, SARATOGA SPRINGS, NY (US); GEORGE KAPLAN, SARATOGA SPRINGS, NY (US)

(72) Inventors: AARON RAY BATKER PRITZKER, GREENFIELD CENTER, NY (US); JOSHUA PATRICK NIXON, SARATOGA SPRINGS, NY (US); JOHN HOWE, SARATOGA SPRINGS, NY (US); ALEXANDER GAILOR, SARATOGA SPRINGS, NY (US); GEORGE KAPLAN, SARATOGA SPRINGS, NY (US)

(21) Appl. No.: 13/622,856

(22) Filed: Sep. 19, 2012

(51) Int. Cl. H05K 7/20; F28D 15/00

(52) U.S. Cl. 165/104.28; 165/104.33

(57) ABSTRACT

Devices, systems, and methods for cooling electronic component heat spreaders, for example, a heat spreader mounted over a CPU of personal computer, are disclosed. The devices, systems, and methods employ a housing having an internal cavity with an open bottom; a gasket positioned between the open bottom and the heat spreader; a cooling fluid inlet to the housing adapted to direct a cooling fluid upon the heat spreader in a direction substantially normal to heat spreader; and a cooling fluid outlet positioned to remove the cooling fluid from the housing. Though aspects of the invention can be applied to any electronic component that can benefit from enhanced heat dissipation, users of high-performance computer equipment, such as, gamers, scientific and mathematical modelers, and engineers may find aspects of the invention particularity advantageous.

### BACKGROUND OF THE INVENTION

1. Technical Field

The present invention generally relates to cooling electronic components, in particular, to cooling electronic components by introducing fluid flows to the surfaces of heat spreaders mounted above electronic components, for example, central processing units (CPUs) or microprocessors.

2. Description of Related Art

Heat is a computer's worst enemy. In every computer component, the generation and buildup of heat and the failure to dissipate this heat can cause the excess noise, unreliability, and performance bottlenecks that have plagued the personal and enterprise computing industries for years. The devastating effect of heat on computer components can be most easily felt when a part fails from overheating. According to researchers at Intel, “increasing [hard disk drive] temperature by 5 degrees C. has the same effect on reliability as switching from 10 percent to 100 percent [hard disk drive] workload.” Overheating of the processor, memory, and/or graphics card in a computer is also notorious for causing seemingly random shutdowns and “freezes.” For example, particularly severe cases of overheating, such as, the infamous Xbox 360 “Red Ring of Death” problem, can cause permanent damage to electronic components that can cost thousands of dollars to remedy.

A slightly less obvious effect of inadequate cooling in computer components comes in the form of performance slowdowns. Since heat increases substantially linearly with processor clock speed, modern processors are typically scaled down to lower clock speeds when computer component temperatures get too high. For example, it is generally believed in the art that when one supplier's graphics card became commercially available in March of 2010, it had to ship with more than 6% of its processing units disabled because even top of the line air coolers could not handle the full heat generated by the components in the card.

It is recognized in the art that issues related to heat generation in computer components and its dissipation may typically be encountered by the users of high-performance computer equipment, such as, so-called “gamers,” scientific and mathematical modelers, and engineers. While this limited user community may limit the potential market share of a high-performance cooling product, it is generally known that several commercial computer manufacturers have partnered with companies that provide computer component cooling systems directly to the makers of powerful gaming computers and workstations.

The computer industry has developed and marketed, and is expected to continue to develop and market, computers and computer components that generate increasing heat loads. However, the cooling technology available to dissipate the increased heat loads has generally advanced little since the 1990s. For example, traditional air-cooling technology has become louder and more expensive. In addition, attempts to address the limitation of air-cooling technology have included massive copper heat pipes, which increase the prices of high-end coolers, and increasingly more numerous, more powerful, and louder fans. However, these louder, more powerful fans have become annoyances to consumers attempting to work—or play—in a quiet computer environment.

Attempts have been made to address the problems related to dissipating heat in ever faster and hotter computers and computer components. For example, U.S. Pat. No. 6,313,990 and U.S. Pat. No. 6,992,887 and U.S. Patent Publication US 20080002363 all disclose methods and devices for cooling electronic components with liquid coolant. However, these attempts, as well others, to address heat dissipate in electronic components have disadvantages that remain unresolved. Aspects of the present invention overcome the disadvantages of the existing art and, in its many embodiments and aspects, provide advantages over the present art.

### SUMMARY OF THE INVENTION

The present invention overcomes the disadvantages of the prior art by providing a flow of fluid coolant directly to heat spreaders, for example, without any intervening structures or obstacles. One embodiment of the invention is a device for cooling an electronic component heat spreader, the device including, consisting of, or comprising: a housing having an internal cavity, a closed top, and an open bottom, the open bottom having a peripheral surface; an elastomeric material positioned between the peripheral surface of the open bottom and the heat spreader, the elastomeric material adapted to minimize passage of fluid between the peripheral surface and the heat spreader; a cooling fluid inlet positioned in the top of the housing, the cooling fluid inlet adapted to direct a cooling fluid upon the heat spreader wherein the cooling fluid impinges the heat spreader in a direction substantially normal to a surface of the heat spreader wherein thermal energy is transferred from the heat spreader to the cooling fluid; and a cooling fluid outlet positioned to remove the cooling fluid from the housing.

The electronic component may be a central processing unit (CPU), a microprocessor, a capacitor, a resistor, a memory device, and an integrated circuit, among other components. In one aspect, the heat spreader comprises a thermally conductive thin plate, for example, a copper plate. In another aspect, the open bottom of the housing comprises a polygonal-shaped open bottom, for example, a square open bottom or a rectangular open bottom.

In another aspect, the cooling fluid inlet comprises a single fluid inlet, and the direction substantially normal to the surface of the heat spreader comprises a direction making an angle ranging from 85 degrees to 95 degrees with the surface of the heat spreader.

In another aspect, the device further comprises a heat exchanger having a fluid inlet operatively connected to the cooling fluid outlet and a fluid pressurizing device having an inlet operatively connected to an outlet of the heat exchanger and an outlet operatively connected to the cooling fluid inlet.

Another embodiment of the invention is a method for cooling an electronic component heat spreader, the method including, consisting of, or comprising: mounting a housing having an internal cavity, a closed top, and an open bottom to the heat spreader, the open bottom having a peripheral surface; fluid sealing an interface between the peripheral surface of the open bottom and the heat spreader; introducing cooling fluid to a cooling fluid inlet positioned in the top of the housing; directing the cooling fluid upon the heat spreader wherein the cooling fluid impinges the heat spreader in a direction substantially normal to a surface of the heat spreader wherein thermal energy is transferred from the heat spreader to the cooling fluid; and removing the cooling fluid from the housing through a cooling fluid outlet in the housing.

In one aspect, directing the cooling fluid upon the heat spreader in a direction substantially normal to the surface of the heat spreader comprises directing the cooling fluid upon the heat spreader in a direction making an angle ranging from 85 degrees to 95 degrees with the surface of the heat spreader.

A further embodiment of the invention is a device for cooling a central processing unit (CPU) heat spreader, the device including, consisting of, or comprising: a housing having an internal cavity, a closed top, and a polygonal open bottom, the polygonal open bottom having a peripheral surface; an elastomeric material positioned between the peripheral surface of the open bottom and a surface of the heat spreader, the elastomeric material adapted to minimize passage of fluid between the peripheral surface of the open bottom and the surface of the heat spreader; a single cooling fluid inlet positioned in the top of the housing, the single cooling fluid inlet adapted to direct a cooling fluid upon the surface of the microprocessor heat spreader wherein the cooling fluid impinges the heat spreader in a direction substantially normal to the surface of the heat spreader wherein thermal energy is transferred from the heat spreader to the cooling fluid; and a cooling fluid outlet positioned to remove the cooling fluid from the housing after the thermal energy is transferred to the cooling fluid. In one aspect, the device further comprises a mounting plate adapted to retain the housing, the mounting plate adapted to mount to a motherboard.

These and other aspects, features, and advantages of this invention will become apparent from the following detailed description of the various aspects of the invention taken in conjunction with the accompanying drawings.

### BRIEF DESCRIPTION OF THE DRAWINGS

The subject matter, which is regarded as the invention, is particularly pointed out and distinctly recited in the claims at the conclusion of the specification. The foregoing and other objects, features, and advantages of the invention will be readily understood from the following detailed description of aspects of the invention taken in conjunction with the accompanying drawings in which:

FIG. 1 is a perspective view of a motherboard of a computer having electronic components with a heat spreader for which aspects of the invention can be applied.

FIG. 2 is a partial exploded perspective view of the motherboard shown in FIG. 1.

FIG. 3 is a perspective view of motherboard shown in FIGS. 1 and 2 employing one aspect of the invention.

FIG. 4 is an exploded perspective view of the aspect of the invention shown in FIG. 3.

FIG. 5 is a top plan view of the aspect of the invention shown in FIG. 3.

FIG. 6 is a bottom view of the aspect of the invention shown in FIG. 3.

FIG. 7 is a cross section view of the aspect of the invention shown in FIG. 3 as viewed along section lines 7-7 in FIG. 3.

FIG. 8 is a top perspective view of another aspect of the invention.

FIG. 9 is a bottom perspective view of the aspect of the invention shown in FIG. 8.

FIG. 10 is a cross section view of the aspect of the invention shown in FIG. 8 as viewed along section lines 10-10 in FIG. 8.

FIG. 11 is a perspective view of the motherboard shown in FIGS. 1 and 2 employing another aspect of the invention.

FIG. 12 is an exploded perspective view of the aspect of the invention shown in FIG. 11.

FIG. 13 is a cross section view of the aspect of the invention shown in FIG. 11 as viewed along section lines 13-13 in FIG. 11.

FIGS. 14 and 15 are bar charts of comparative performance test data between aspects of the invention and examples of existing art.

### DETAILED DESCRIPTION OF THE INVENTION

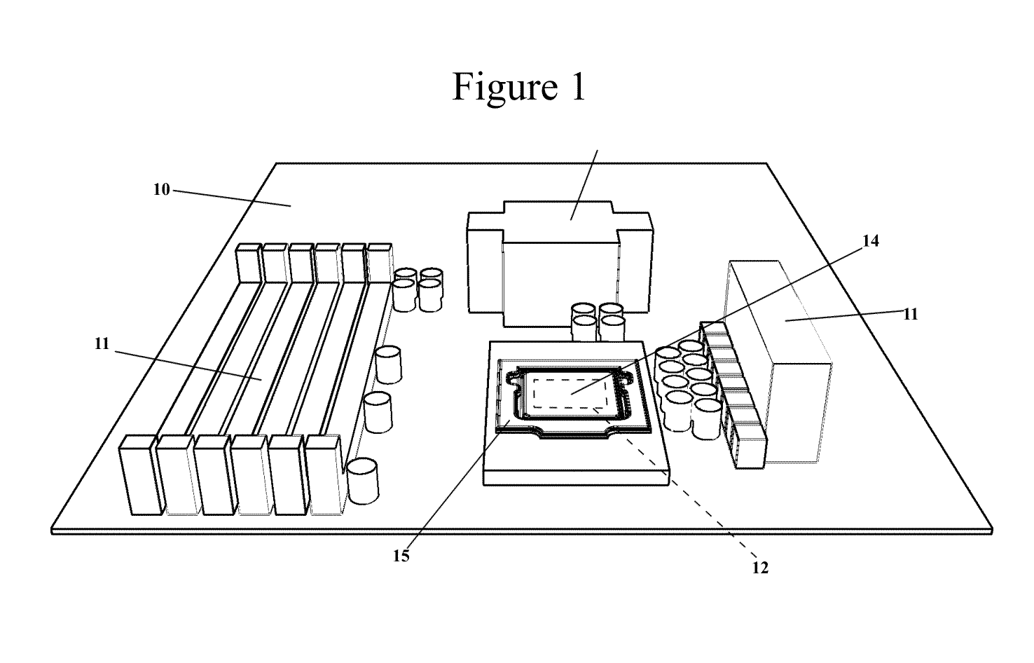

FIG. 1 is a perspective view of a motherboard 10 of a computer (not shown) having electronic components 12 (shown in phantom) having a heat spreader 14 for which aspects of the invention can be applied. As is typical, motherboard 10 may include an assortment of components 11, for example, expansion slots, random access memory, voltage regulators, capacitors, and passive heat sinks, among other components, that are not related to aspects of the present invention. Though aspects of the invention may be applied to any electronic component, for example, any electronic component on motherboard 10 for which it is beneficial to remove heat, for example, a central processing unit (CPU), a memory module, and a heat sink, among others, in the aspect of the invention shown in FIG. 1, the electronic component used to illustrate aspects of the present invention is a CPU 12 having heat spreader 14. As is typical in the art, CPU 12 with heat spreader 14 may be retained on motherboard 10 by a retaining mechanism 15, for example, a spring clip retainer.

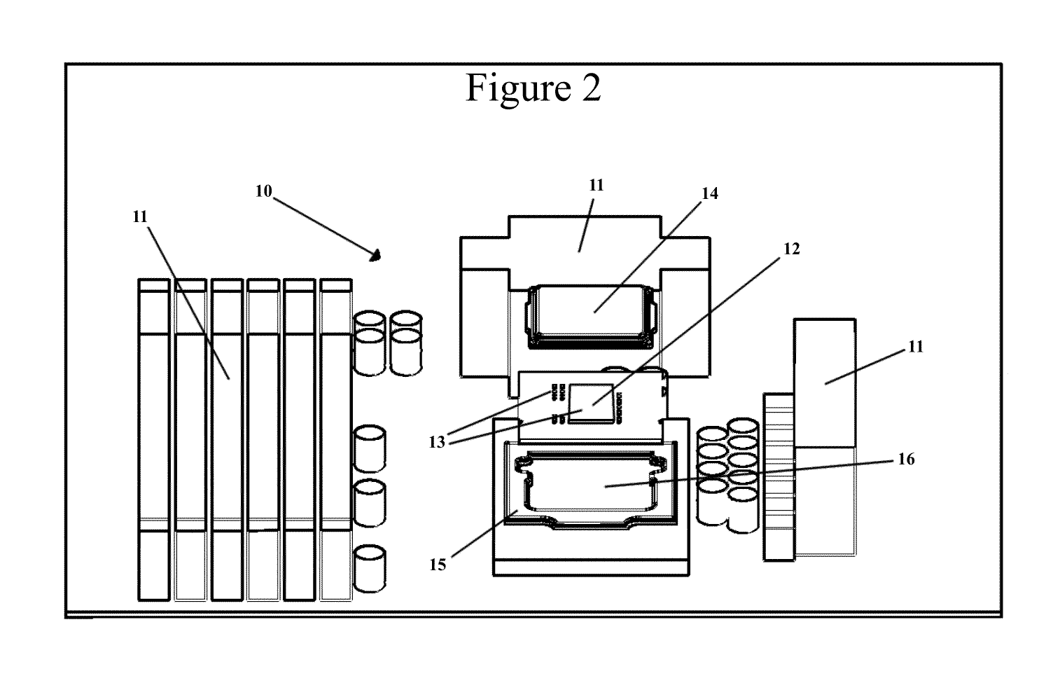

FIG. 2 is a partial exploded perspective view of the motherboard 10 shown in FIG. 1. As shown in FIG. 2, CPU 12 having internal components 13, for example, resistors, memory devices, capacitors, and/or integrated circuits, microprocessors, among other components, is typically mounted in a foot print 16 having appropriate connectors on motherboard 10, and heat spreader 14 is mounted over CPU 12 above components 13 to assist in dissipating heat generated by components 13. As known in the art, and as shown and used herein and in the claims included herein, a “heat spreader” is typically a thermally-conductive thin plate, for example, a thin copper plate, that functions as a heat exchanger between electronic components, such as, components 13, and the cooler medium above the heat spreader, for example, ambient air propelled by a fan. As its name implies, a “heat spreader” functions to “spread out” the heat generated to facilitate dissipation of the heat, for example, into the ambient air. Though a heat spreader may comprises a thin conductive plate, as shown in FIG. 2, heat spreader 14 may be adapted to engage retaining mechanism 15, for example, have flanges, protections and/or recesses about the perimeter of heat spreader 14 adapted to engage retaining mechanism 15 and or motherboard 10. In contrast to prior art cooling devices, aspects of the present invention introduce cooling fluid to heat spreader 14, or its equivalent, that is in thermal contact with more than one computer component 13, for example, more than one heat generating computer component. Typically, aspects of the invention may be used to cool multiple components which may be positioned and in thermal contact with heat spreader 14. Though aspects of the invention can be used to cool multiple components 13 and/or multiple heat spreaders 14, in one aspect, only a single heat spreader 14 is exposed to a cooling fluid, where one or more components 13 are positioned below the single heat spreader 14.

According to one aspect of the invention, heat spreader 14 may be a thin metallic plate, such as, a copper or a steel plate, or a non-metallic plate, for example, made from a non-metallic conductor. Heat spreader 14 may have a length ranging from about 0.25 to about 6 inches, a width ranging from about 0.25 to about 6 inches, and a thickness ranging from 0.0156 ( 1/64) inches to 0.25 inches.

Contrary to prior cooling devices, aspects of the present invention, direct cooling fluid directly on a computer component, for example, an existing integral computer component, such as, a heat spreader 14, that is, without any intervening heat sinks, structures, or obstructions that can interfere with heat dissipation and increase the weight and cost of prior art cooling devices.

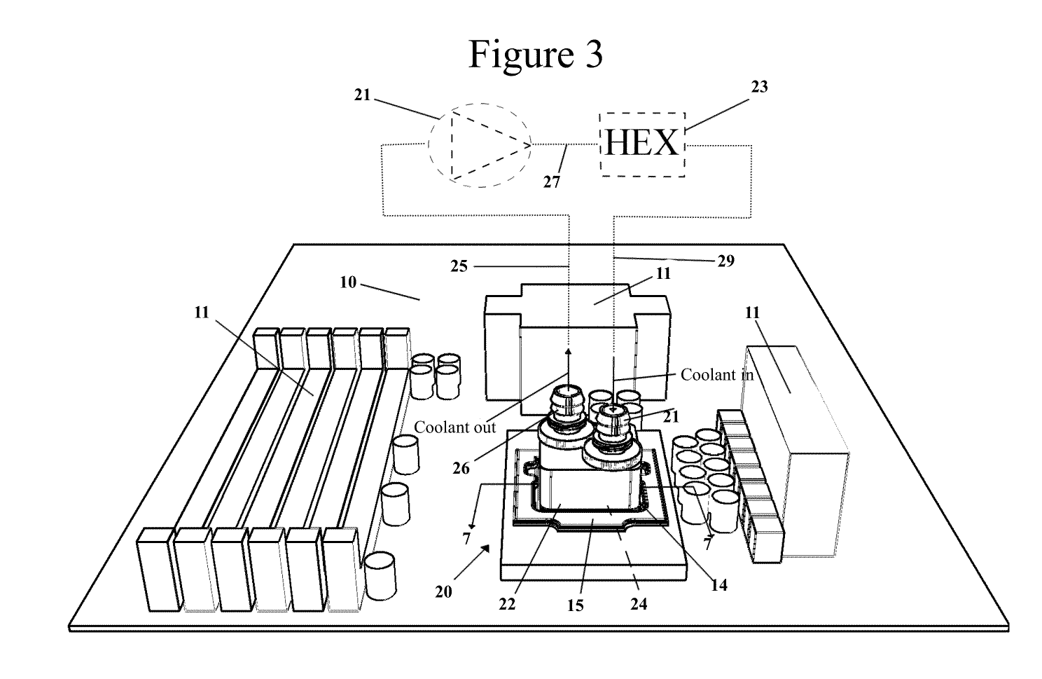

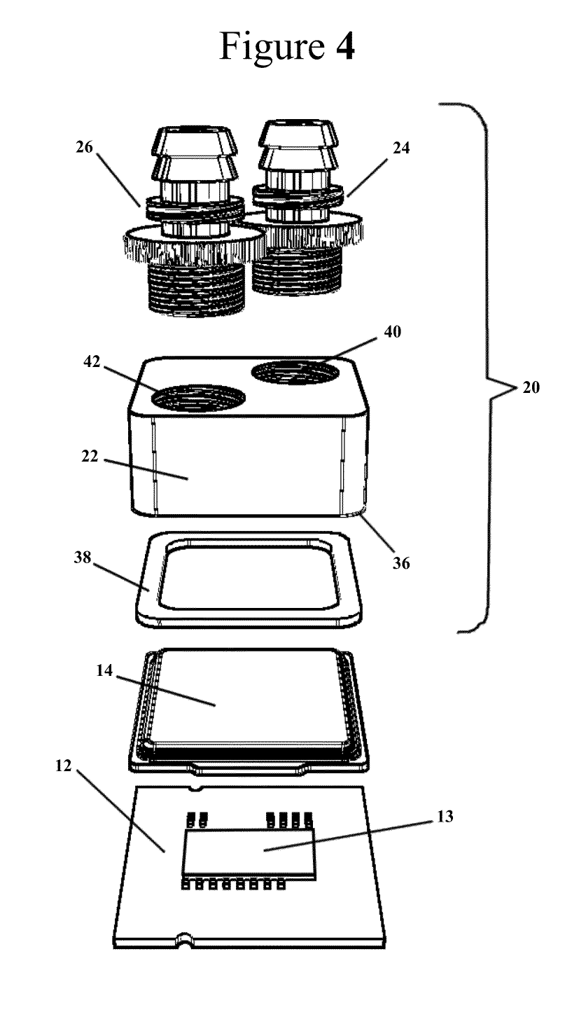

FIG. 3 is a perspective view of motherboard 10 shown in FIGS. 1 and 2 employing one aspect of the invention. FIG. 4 is an exploded perspective view of the aspect of the invention shown in FIG. 3. As shown in FIGS. 3 and 4, in one embodiment the invention is a system and/or a device 20 for cooling an electronic component heat spreader 14. The system and/or device 20 typically include a housing 22 sized and adapted to contact heat spreader 14. The housing 22 includes at least one cooling fluid inlet conduit 24 to the housing 22 and at least one cooling fluid outlet conduit 26 from the housing 22. The cooling fluid introduced to cooling fluid inlet conduit 24 (and to any housing disclosed herein) and discharged by cooling fluid outlet conduit 26 may be a liquid, for example, an electrically-conducting or a non-electrically conducting liquid, such as, water (preferably, non-conducting, de-ionized water) or a gas, for example, an electrically-conducting or a non-electrically conducting gas, such, air, nitrogen, or an inert gas (such as, helium). As shown in FIGS. 3 and 4, cooling fluid inlet conduit 24 (and all cooling fluid inlet conduits disclosed herein) and cooling fluid outlet conduit 26 (and all cooling fluid outlet conduits disclosed herein) may comprise conduit fittings, for example, threaded fittings, such, a ¼ inch, G-series British Standard Pipe (BSP) thread fitting, or its equivalent, adapted to engage housing 22. For example, as shown, cooling fluid inlet conduit 24 and cooling fluid outlet conduit 26 may comprise threaded fittings adapted to engage threaded holes 40 and 42, respectively, in housing 22.

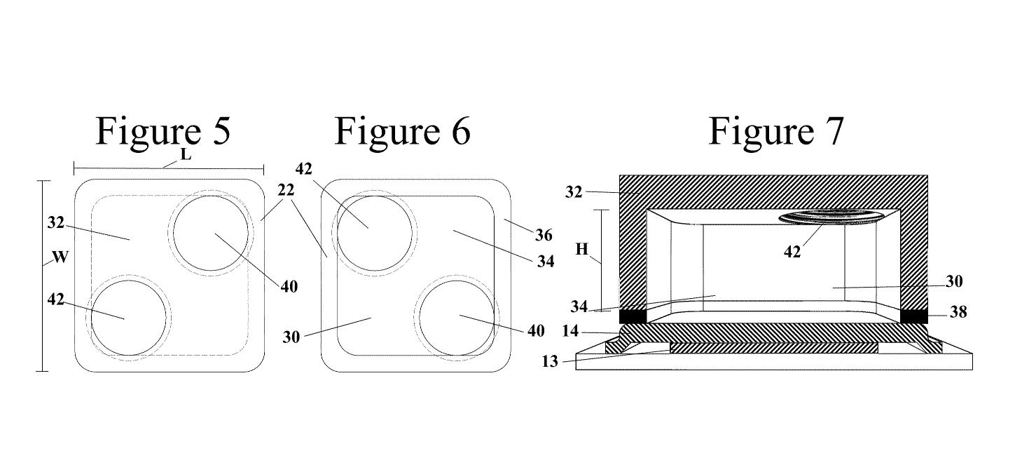

FIG. 5 is a top plan view of one housing 22 and FIG. 6 is a bottom view of one housing 22 that can be used for system 20 shown in FIGS. 3 and 4. FIG. 7 is a cross section view of one housing 22 that can be used for system 20 shown in FIG. 3, as viewed along section lines 7-7 in FIG. 3.

As shown schematically in FIG. 3, according to one aspect of the invention, system 20 may include one or more fluid pressurizing devices 21, for example, a pump or a fan, and one or more heat exchangers (HEX) 23 operatively connected to housing 22. For example, as shown in FIG. 3, in one aspect, the inlet of pump 21 may be operatively connected to the cooling fluid outlet conduit 28 via one or more conduits 25, the outlet of pump 21 may be operatively connected to the inlet of heat exchanger 23 via one or more conduits 27, and the outlet of heat exchanger 23 may be operatively connected to cooling fluid inlet 26 via one or more conduits 29. Conduits 25, 27, and 29, fluid pressurizing device 21, and heat exchanger 23 may include conventional regulation and control devices, for example, valves, sensors, and meters, among others, that can be used to monitor and/or regulate the operation aspects of the invention, including the operation of device 21 and heat exchanger 23. Heat exchanger 23 may include an air handler (not shown), for example, an electric fan adapted to direct a flow of air over or through heat exchanger 23 to assist dissipating heat from heat exchanger 23.

As shown in FIGS. 3 through 7, housing 20 typically includes an internal cavity 30, a closed top 32, and an open bottom 34 exposed to heat spreader 14. Though aspects of the invention may have multiple internal cavities, for example, cavities separated by barriers or baffles, in a preferred aspect, only a single internal cavity 30 is provided in housing 20 (and in other housings disclosed herein). According to an aspect of the invention, open bottom 34 typically includes a peripheral surface 36 (see FIG. 6) adapted to contact heat spreader 14. Housing 20 may be fabricated from plastic, for example, a polycarbonate plastic or an acrylic plastic, or a metal, for example, aluminum, copper, or stainless steel.

As suggested by the above discussion, the dimensions, for example, the width, W and length L of housing 20 may be dictated by the size of the heat spreader 14 to which housing 20 is mounted. In one aspect, width W may range from about 0.25 to about 6 inches, but is typically about 0.75 inches to about 1.5 inches. Similarly, length L may range from about 0.25 to about 6 inches, but is typically about 0.75 inches to about 1.5 inches.

The inventors have found that the internal height H (see FIG. 7) of internal cavity 30 of housing 20 may affect the performance of aspects of the invention. For example, depending upon the height H, the dissipation of heat from heat spreader 14 may vary. For example, in one aspect, internal height H may range from about 0.010 inches to about 5 inches, but is typically ranges from about 0.0625 to about 1 inch.

In one aspect, as shown in FIGS. 4 and 7, an elastomeric material 38, for example, a seal or gasket, may be positioned between the peripheral surface 36 of the open bottom 34 and the heat spreader 14. The elastomeric material 38 may be shaped to approximate the geometry the peripheral surface 36 and be adapted to minimize the passage of fluid between the peripheral surface 36 and the heat spreader 14. The elastomeric material 38, or gasket, may be the only structure that contacts heat spreader 14, while the coolant removes heat from heat spreader 14. The elastomeric material 38 may be a natural polymer, such as, polyisoprene rubber, or a synthetic polymer, such as, a neoprene, a thermoplastic elastomer, a thermoplastic rubber, and a polyvinyl chloride, or an ethylene propylene diene monomer (EPDM) rubber, and the like. Elastomeric material 38 may have a thickness ranging from about 0.010 inches to about 0.5 inches (in the uncompressed state), but is typically ranges from about 0.05 to about 0.125 inches, for example, about 0.0625 inches.

As shown most clearly in FIGS. 6 and 7, the open bottom 34 of housing 20 may be substantially rectangular or square in shape, for example, with sharp, rounded, or chamfered external and/or internal corners. In one aspect, the open bottom 34 of housing 20 may be fashioned in any polygonal shape, for example, having 3 or more sides. It will be understood by those of skill in the art that the shape of the open bottom 34 of housing 20 may be fashioned to comply with the shape of the heat spreader 14 to which aspects of the invention are applied, and may vary in shape accordingly.

As also shown in FIGS. 3 through 7, housing 20 typically includes at least one cooling fluid inlet 40 positioned in the top of the housing 20 and at least one cooling fluid outlet 42 which may also be positioned in the top of housing 20. Though in one aspect, cooling fluid inlet 40 is preferably positioned in the top of housing 20, for example, directing fluid downward onto heat spreader 14, in other aspects, cooling fluid inlet 40 may be located in any position in housing 20, for example, through any one or more of the sidewalls of housing 20. Cooling fluid outlet 42 may be positioned anywhere in housing 20, for example, through any one or more of the sidewalls of housing 20. As shown in FIGS. 3 through 7, in one aspect, a single cooling fluid inlet 40 may be provided, for example, positioned in the top of the housing 20 and a single cooling fluid outlet 42 may be provided, for example, also positioned in the top of housing 20. As shown in FIG. 7, cooling fluid inlet 40 and cooling fluid outlet 42 may be threaded to engage conduits/fittings 24 and 26 shown in FIGS. 3 and 4.

According to one aspect of the invention, the cooling fluid inlet 40 is adapted to direct a cooling fluid, for example, a stream of cooling fluid, upon the heat spreader 14 wherein thermal energy is transferred from the heat spreader to the cooling fluid. Specifically, the cooling fluid inlet may be adapted to direct cooling fluid upon heat spreader 14 wherein the cooling fluid impinges the heat spreader 14 in a direction substantially normal to the surface of the heat spreader 14. According to some aspects of the invention, the expression “substantially normal” may comprise a direction making an angle ranging from 85 degrees to 95 degrees with the surface of the heat spreader. This deviation from true perpendicularity may be provided without detracting from the scope and efficacy of the present invention. Such deviations from true perpendicularity may simply be attributed to manufacturing tolerances.

An examination of FIGS. 3 through 7 reveals a further advantageous features of some aspects of the invention: the cooling fluid inlet 40 and the cooling fluid outlet 42, and the related cooling fluid inlet conduit/fitting 24 and the cooling fluid outlet conduit/fitting 26, may be interchangeable. In other words, the flow of coolant through housing 20 may be introduced through either the cooling fluid inlet 40 or the cooling fluid outlet 42 without detracting from the performance of the invention. In one aspect, housing 20 may be symmetric about a plane where, for example, housing 20 may be mounted to heat spreader 14 in multiple orientations without detracting from performance. In addition, this interchangeable/symmetric aspect of the invention can also facilitate manufacture, handling, installation, and servicing of some aspects of the invention. In addition, a further advantage is that some aspects of the invention may have few or no moving parts, which can be prone to wear or require servicing.

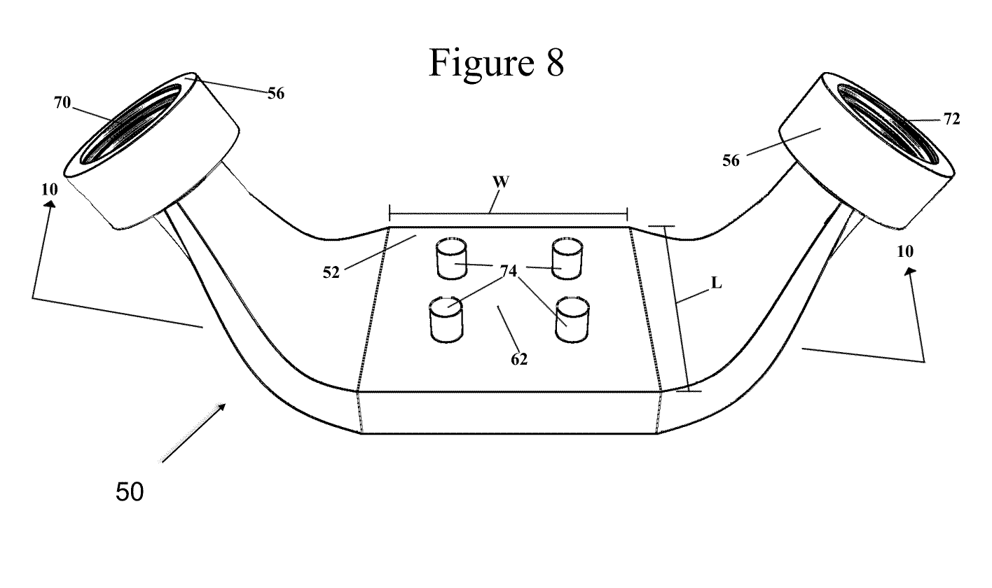

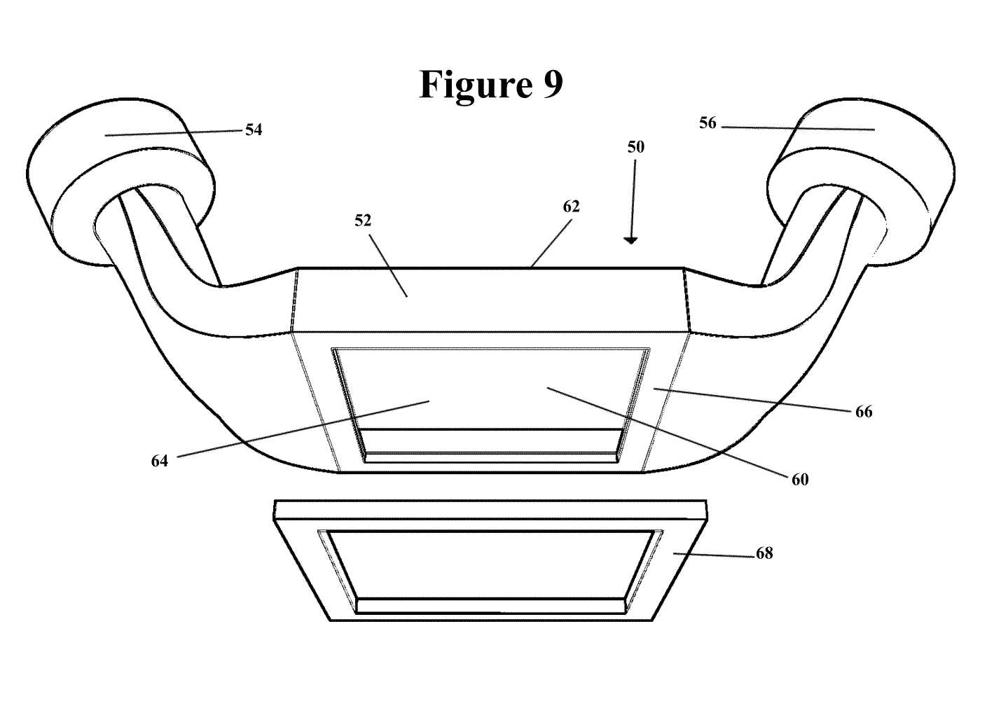

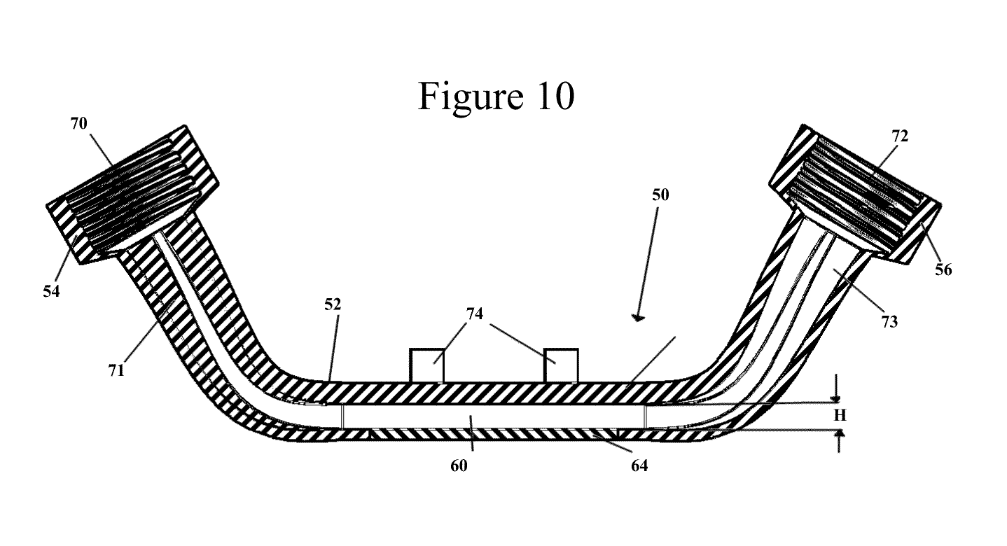

FIG. 8 is a top perspective view of another aspect of the invention. As shown in FIG. 8, one embodiment of the invention is a device 50 for cooling an electronic component heat spreader, for example, heat spreader 14 shown in FIGS. 1 and 2. Similar to earlier embodiments, device 50 typically includes a housing 52 sized and adapted to contact a heat spreader. The housing 52 includes at least one cooling fluid inlet conduit 54 to the housing 52 and at least one cooling fluid outlet conduit 56 from the housing 52. As shown in FIG. 8, cooling fluid inlet conduit 54 and cooling fluid outlet conduit 56 may typically be adapted to engage a conduit or fitting, for example, they may be internally threaded. The cooling fluid introduced to inlet conduit 54 and discharged by outlet conduit 56 may be a liquid, for example, water (preferably, non-conducting, de-ionized water) or a gas, for example, air, nitrogen, or an inert gas (such as, helium). FIG. 9 is a bottom perspective view of device 50 shown in FIG. 8 and FIG. 10 is a cross section view of device 50 shown in FIG. 8 as viewed along section lines 10-10 in FIG. 8.

Though not shown in FIGS. 8 through 10, it is envisioned that device 50 may be operatively connected to one or more fluid pressurizing devices, for example, a pump or a fan, one or more heat exchangers (HEX), and appropriate conduits in a manner similar to what is shown for device 20 in FIG. 3.

As shown most clearly in FIG. 10, device 50 includes a housing 52 having an internal cavity 60, a closed top 62, and an open bottom 64 adapted to be exposed to a heat spreader, such as, heat spreader 14. Closed top 62 may include one or more pins 74 to assist in handling housing 52 and/or to assist in dissipating heat from housing 52. According to an aspect of the invention, open bottom 64 typically includes a peripheral surface 66 (see FIG. 9) adapted to contact a heat spreader 14. Similar to housing 20, housing 52 may be fabricated from plastic, for example, a polycarbonate plastic or an acrylic plastic, or a metal, for example, aluminum, copper, or stainless steel.

As suggested by the above discussion, the dimensions, for example, the width W, length L, and internal height H (see FIG. 10) of housing 52 may be dictated by the size of the heat spreader to which housing 52 is mounted. In one aspect, width W may range from about 0.25 to about 6 inches, but is typically about 0.75 inches to about 1.5 inches. Similarly, length L may range from about 0.25 to about 6 inches, but is typically about 0.75 inches to about 1.5 inches. The internal height H of housing 52 may range from about 0.010 inches to about 5 inches, but is typically ranges from about 0.0625 to about 1 inch.

In one aspect, an elastomeric material 68 (see FIG. 9), for example, a seal or gasket may be positioned between the peripheral surface 66 of the open bottom 64 and the heat spreader. The elastomeric material 68 may be adapted to minimize the passage of fluid between the peripheral surface 66 and the heat spreader. Similar to elastic material 38 discussed above, elastomeric material 68 may be a natural polymer, such as, polyisoprene rubber, or a synthetic polymer, such as, EPDM, and the like. Elastic material 68 may perform similar functions as and have dimensions similar to elastic material 38.

As shown most clearly in FIG. 9, the open bottom 64 of housing 52 may be substantially rectangular or square in shape, for example, with sharp, rounded, or chamfered internal and/or external corners. In one aspect, the open bottom 64 of housing 52 may be fashioned in any polygonal shape, for example, having 3 or more sides. It will be understood by those of skill in the art that the shape of the open bottom 64 of housing 52 may be fashioned to comply with the shape of the heat spreader to which device 50 is applied, and may vary in shape accordingly.

As shown in FIGS. 8 through 10, housing 52 typically includes at least one cooling fluid inlet 70 positioned to introduce a fluid to internal cavity 60 of housing 52 and at least one cooling fluid outlet 72 positioned to remove a fluid from internal cavity 60. Though in one aspect, cooling fluid inlet 70 is preferably positioned in the top of housing 20, for example, directing fluid substantially normal to the surface of a heat spreader (not shown), as shown in FIG. 10, in one aspect, device 50 is adapted to direct fluid across a surface of a heat spreader for example, in a direction substantially parallel to the surface of a heat spreader, or at an angle oblique to the plane of the surface of a heat spreader. For example, in one aspect, the device 50 may introduce a flow to the surface of a heat spreader that has a direction of flow of fluid oriented at an angle to the plane of the heat spreader for example, and angle ranging form about 5 degrees to 75 degrees, for example, between about 30 degrees and about 60 degrees with the plane of the surface of the heat spreader of the heat across downward onto a heat spreader. In other aspects, cooling fluid inlet 70 may be located in any position in housing 52, for example, through any one or more of the side walls of housing 52. Cooling fluid outlet 72 may be positioned anywhere in housing 52, for example, through any one or more of the sidewalls of housing 52. As shown in FIGS. 8 through 10, in one aspect, a single cooling fluid inlet 70 may be provided, for example, positioned in a sidewall of housing 52 and directed substantially parallel to the plane of the surface of the heat spreader (not shown) and to the plane of the peripheral surface 66.

As shown most clearly in FIG. 10, in one aspect, cooling fluid inlet 70 may communicate with a passage 71 that provides a transition from the inlet 70 to the internal cavity 60. In addition, cooling fluid outlet 72 may communicate with a passage 73 that provides a transition from internal cavity 60 to outlet 72. As also shown in FIGS. 8 through 10, device 50 may typically include a single cooling fluid outlet 72, for example, also positioned in a sidewall of housing 52. The angle of orientation of cooling fluid outlet 72 may be substantially the same or vary from the angle of orientation of the cooling fluid inlet 70 with respect to the plane of the surface of the heat spreader and the peripheral surface 66.

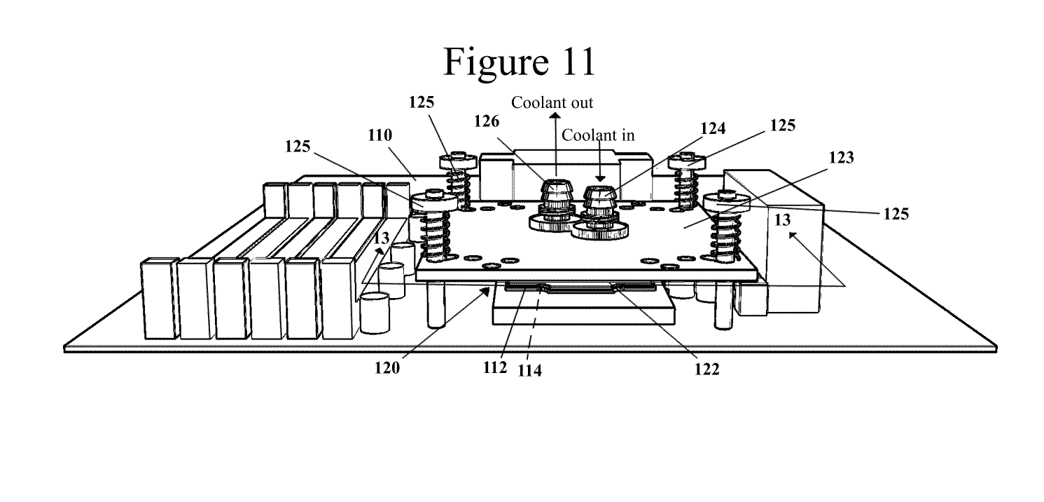

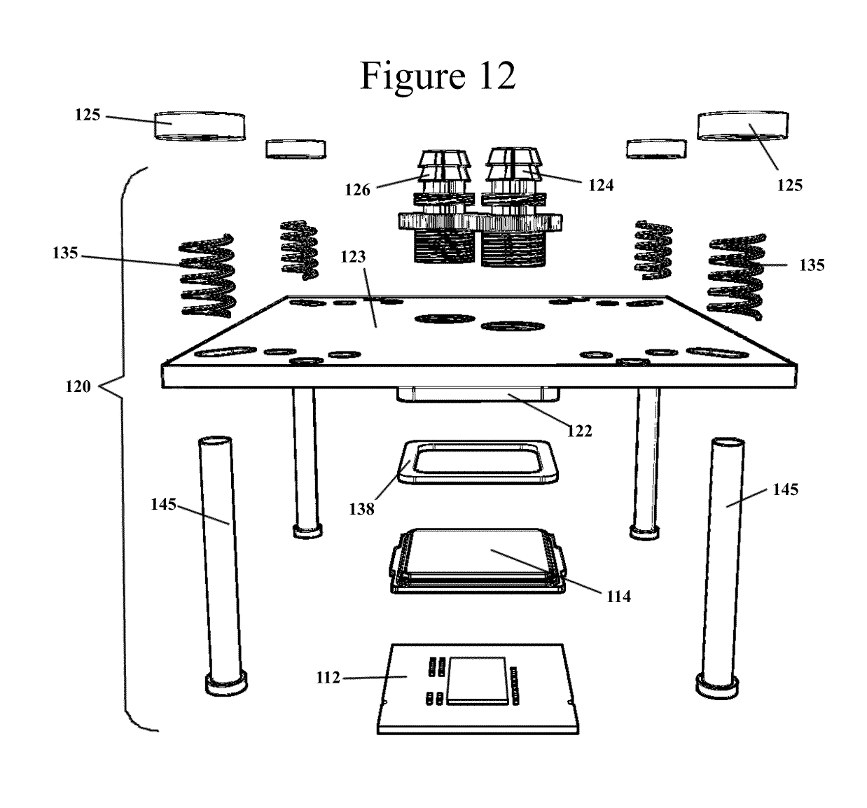

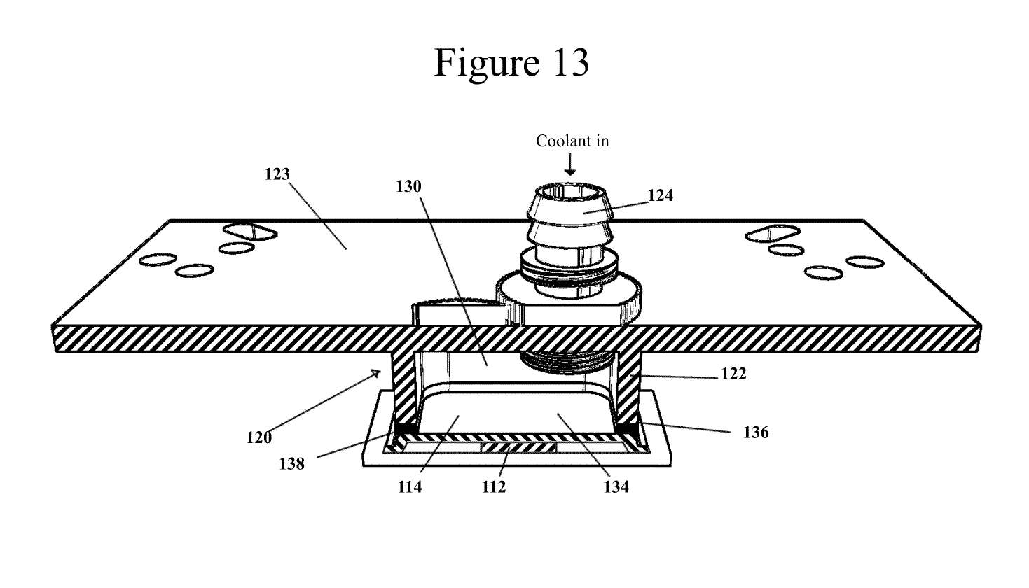

FIG. 11 is a perspective view of motherboard 110 similar to motherboard 10 shown in FIGS. 1 and 2 employing another aspect of the invention. As shown in FIG. 11, this embodiment of the invention is a system or device 120 for cooling an electronic component heat spreader heat spreader 114, which may be similar to heat spreader 14 shown in FIGS. 1 and 2. FIG. 12 is an exploded perspective view of system or device 120 shown in FIG. 11 and FIG. 13 is a perspective cross section view of device 120 shown in FIG. 11 as viewed along section lines 13-13 in FIG. 11.

Similar to earlier embodiments, system or device 120 typically includes a housing 122 sized and adapted to contact a heat spreader. The housing 122 includes at least one cooling fluid inlet conduit/fitting 124 to the housing 122 and at least one cooling fluid outlet conduit/fitting 126 from the housing 122. Again, similar to earlier aspects, the cooling fluid introduced to inlet conduit/fitting 124 and discharged by outlet conduit/fitting 126 may be a liquid, for example, water (preferably, non-conducting, de-ionized water) or a gas, for example, air, nitrogen, or an inert gas (such as, helium). However, in the embodiment shown in FIGS. 11 through 13, device 120 includes a mounting or interface plate 123 to which housing 122 is mounted. In this aspect, mounting plate 123 can be used to facilitate mounting of aspects of the invention to the motherboard 110, for example, via a plurality of conventional mechanical fasteners 125 adapted to engage mounting plate 123 and the motherboard 110. The mounting plate 123 and the fasteners 125, for example, threaded fasteners may comply with existing motherboard interface standards. As shown most clearly in FIG. 13, fasteners 125 may include a nut, which retains a spring 135, where the nut is threaded to a mounting post 145 adapted to mount to the motherboard (not shown). Aspects of the invention having mounting plate 123 facilitate mounting of aspects of the invention to conventional, or standard consumer computers, among other devices. Aspects of the present invention, for example, having mounting plate 123, permit the installation of aspects of the invention to computers, and other devices, both quickly and easily.

Though not shown in FIGS. 11 through 13, it is envisioned that device 120 may be operatively connected to one or more fluid pressurizing devices, for example, a pump or a fan, one or more heat exchangers (HEX), and appropriate conduits in a manner similar to what is shown for devices 20 in FIG. 3.

As shown most clearly in FIG. 13, device 120 includes a housing 122 having an internal cavity 130, a closed top 132, and an open bottom 134 adapted to be exposed to a heat spreader 114. According to an aspect of the invention, open bottom 134 typically includes a peripheral surface 136 (see FIG. 13) adapted to contact heat spreader 114. However, as noted above, and in contrast to earlier aspects of the invention, device 120 includes a mounting or interface plate 123 to which housing 122 is mounted, for example, fixedly or removably mounted, which provides a means for mounting housing 122 to motherboard 110, for example, with mechanical fasteners 125. In one aspect, mounting plate 123 may be metallic, for example, aluminum or stainless steel, or non-metallic, for example, a plastic. Mounting plate 123 may have a width, length, and thickness height dictated by the size of the heat spreader 114 or motherboard to 110 which device 120 is mounted. In one aspect, width of mounting plate 123 may range from about 2 inches to about 6 inches, but is typically about 3 inches to about 4 inches, for example, about 3.5 inches. Similarly, the length of mounting plate 123 may range from about 3 inches to about 7 inches, but is typically about 4 to about 5 inches, for example, about 4.5 inches. The thickness of mounting plate 123 may range from about 0.0625 ( 1/16) inches to about 2 inches, but is typically ranges from about 0.125 (⅛) inches to about 0.25 (¼) inches.

Similar to housings 20 and 52, housing 122 of device 120 may be fabricated from plastic, for example, a polycarbonate plastic or an acrylic plastic, or a metal, for example, aluminum, copper, or stainless steel

As suggested by the above discussion, the dimensions, for example, the width W, length L, and internal height H of housing 122 may be dictated by the size of the heat spreader to which housing 52 is mounted. In one aspect, width W of housing 122 may range from about 0.25 to about 6 inches, but is typically about 0.75 inches to about 1.5 inches. Similarly, length L may range from about 0.25 to about 6 inches, but is typically about 0.75 inches to about 1.5 inches. The internal height H of housing may range from about 0.010 inches to about 5 inches, but is typically ranges from about 0.0625 to about 1 inch.

Housing 122 and mounting plate 123 may be fashioned as a single, integral component, for example, molded or fabricated as a single plastic part. However, housing 122 and mounting plate 123 may comprise two or more individual parts that may be integrated during assembly onto the motherboard 110. For example, housing 122 and mounting plate 123 may be assembled using mechanical fasteners, an adhesive, by interference fit, and/or by snap fit, for example, using deflectable, engagable projections and/or recesses.

In one aspect, as in earlier aspects, an elastomeric material 138, for example, a seal or gasket, may be positioned between the peripheral surface 136 of the open bottom 134 and the heat spreader 114. The elastomeric material 138 may be adapted to minimize the passage of fluid between the peripheral surface 136 and the heat spreader 114. Similar to elastic material 38 discussed above, elastomeric material 138 may be a natural polymer, such as, polysisoprene rubber, or a synthetic polymer, such as, EPDM and the like. Elastic material 138 may perform similar functions as and have dimensions similar to elastic material 38.

The open bottom 134 of housing 122 may be substantially rectangular or square in shape, for example, with sharp, rounded, or chamfered internal and/or external corners. In one aspect, the open bottom 134 of housing 122 may be fashioned in any polygonal shape, for example, having 3 or more sides. It will be understood by those in the art that the shape of the open bottom 134 of housing 122 may be fashioned to comply with the shape of the heat spreader 114 to which device 120 is applied, and may vary in shape accordingly.

As shown in FIGS. 11 through 13, housing 122 typically includes at least one cooling fluid inlet 124 positioned in the top of the housing 122 and at least one cooling fluid outlet 126 which may also be positioned in the top of housing 126. Though in one aspect, for example, similar to housing 20 discussed above, cooling fluid inlet 124 is preferably positioned in the top of housing 122, for example, directing fluid downward onto the heat spreader 114, in other aspects, cooling fluid inlet 124 may be located in any position in housing 122, for example, through any one or more of the sidewalls of housing 122. Cooling fluid outlet 126 may be positioned anywhere in housing 122, for example, through any one or more of the sidewalls of housing 122. As shown in FIGS. 11 through 13, in one aspect, a single cooling fluid inlet 124 may be provided, for example, positioned in the top of the housing 122 and a single cooling fluid outlet 126 may be provided, for example, also positioned in the top of housing 122.

In a manner similar to housing 20, in one aspect, the cooling fluid inlet 124 of housing 122 may be adapted to direct cooling fluid upon a heat spreader 114 wherein the cooling fluid impinges the heat spreader in a direction substantially normal to the surface of the heat spreader. According to some aspects of the invention, the expression “substantially normal” may comprise a direction making an angle ranging from 85 degrees to 95 degrees with the surface of the heat spreader 114 and/or the surface of peripheral surface 136. This deviation from true perpendicularity may be provided without detracting from the scope and efficacy of the present invention. Such deviations from true perpendicularity may simply be attributed to manufacturing tolerances.

With this disclosure and understanding of the physical features of aspects of the invention, it will be readily apparent how the many aspects of the invention may be practiced. For example, with respect to the aspects shown in FIGS. 3 through 7, the embodiment comprising a method for cooling an electronic component heat spreader 14 may be practiced by first mounting a housing 22 having an internal cavity 30, a closed top 32, and an open bottom 34 to the heat spreader 14, the open bottom 34 having a peripheral surface 36. Then the method proceeds by fluid sealing an interface between the peripheral surface 36 of the open bottom 34 and the heat spreader 14. As discussed above, introducing a gasket or elastic material 38 between the peripheral surface 36 and the heat spreader 14 may typically practice this. Then, the step of introducing cooling fluid to a cooling fluid inlet 40 positioned in the top of the housing 22 is practiced and followed by directing the cooling fluid upon the heat spreader 14 wherein the cooling fluid impinges the heat spreader 14 in a direction substantially normal to a surface of the heat spreader 14 wherein thermal energy is transferred from the heat spreader 14 to the cooling fluid. Then, this aspect may be completed by removing the cooling fluid from the housing 22 through a cooling fluid outlet 42 in the housing 22.

### Test Results

Preliminary testing of aspects of the invention have revealed that aspects of the invention can provide an effective means of dissipating heat generated during computer operation, even under highly loaded test conditions. For example, aspects of the invention have been mounted to a heat spreader of a stock Intel i7 920 processor. The processor was operated with Prime95 at full speed on all eight threads and aspects of the invention maintained the temperature of the processor in the acceptable range of 60 to 65 degree C. The inventors have found that operation of the processor under the same conditions but without cooling using aspects of the invention resulted in excess heat generation accompanied by increased likelihood of system instability.

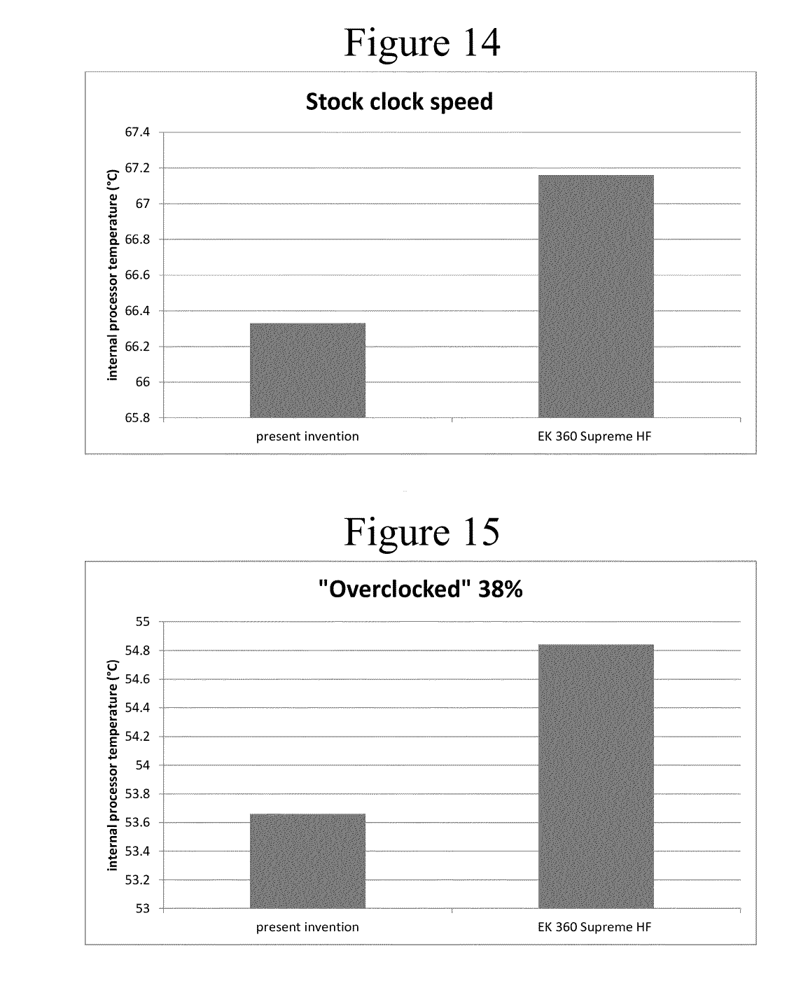

FIGS. 14 and 15 are bar charts of comparative performance test data between aspects of the invention and examples of existing art. FIG. 14 is a bar chart of comparative performance test data between an aspect of the invention and one example of the existing art, specifically, an EK 360 Supreme HF water cooling system, when both are used for a processor operated at conventional, or “stock,” clock speed. The ordinate in FIG. 14 represents the temperature detected (in degrees C.) for the processor die located under the processor's heat spreader. FIG. 15 is a similar bar chart of comparative performance test comparing an aspect of the invention and the EK 360 Supreme HF when both are used for a processor operated at “overclocked” speed, specifically, at an operating speed 38% faster then conventional or stock clock speed. As indicated by the temperatures that appear in FIGS. 14 and 15, aspects of the present invention can markedly decrease component temperatures compared to prior art systems.

As described herein, aspects of the present invention provide devices, systems, and methods for cooling electronic components, for example, processors, among others, by directing a fluid, such as, non-electrically conducting de-ionized water, onto the heat spreader housing the electronic components. The enhanced heat dissipation achieved by aspects of the present invention can be a major assist in overcoming the limitations in present computer systems, for example, limitations in operating speed, that heretofore where otherwise not achievable. Aspects of the invention may be applied to any electrical or electronic component that can benefit from the enhanced dissipation or removal of heat. However, aspects of the invention are recognized particularly beneficial to users of high-performance computer equipment, such as, gamers, scientific and mathematical modelers, and engineers.

While several aspects of the present invention have been described and depicted herein, alternative aspects may be affected by those skilled in the art to accomplish the same objectives. Accordingly, it is intended by the appended claims to cover all such alternative aspects as fall within the true spirit and scope of the invention.

1. A device for cooling an electronic component heat spreader, the device comprising:
a housing having an internal cavity, a closed top, and an open bottom, the open bottom having a peripheral surface;
an elastomeric material positioned between the peripheral surface of the open bottom and the heat spreader, the elastomeric material adapted to minimize passage of fluid between the peripheral surface and the heat spreader;
a cooling fluid inlet positioned in the top of the housing, the cooling fluid inlet adapted to direct a cooling fluid upon the heat spreader wherein the cooling fluid impinges the heat spreader in a direction substantially normal to a surface of the heat spreader wherein thermal energy is transferred from the heat spreader to the cooling fluid; and
a cooling fluid outlet positioned to remove the cooling fluid from the housing.

2. The device as recited in claim 1, where in the heat spreader comprises a thermally-conductive thin plate.

3. The device as recited in claim 1, wherein the open bottom comprises a polygonal-shaped open bottom.

4. The device as recited in claim 3, wherein the polygonal-shaped open bottom comprises one of square open bottom and a rectangular open bottom.

5. The device as recited in claim 1, wherein the cooling fluid inlet comprises a single fluid inlet.

6. The device as recited in claim 1, wherein the direction substantially normal to the surface of the heat spreader comprises a direction making an angle ranging from 85 degrees to 95 degrees with the surface of the heat spreader.

7. The device as recited in claim 1, wherein the internal cavity includes an internal height of between 0.05 inches and 0.125 inches.

8. The device as recited in claim 1, wherein the elastomeric material comprises one of a natural and a synthetic polymer.

9. The device as recited in claim 1, wherein the device further comprises a heat exchanger having a fluid inlet operatively connected to the cooling fluid outlet and a fluid pressurizing device having an inlet operatively connected to an outlet of the heat exchanger and an outlet operatively connected to the cooling fluid inlet.

10. The device as recited in claim 1, wherein the electronic component comprises one or more of a central processing unit (CPU), a microprocessor, a capacitor, a resistor, a memory device, and an integrated circuit.

11. A method for cooling an electronic component heat spreader, the method comprising:
mounting a housing having an internal cavity, a closed top, and an open bottom to the heat spreader, the open bottom having a peripheral surface;
fluid sealing an interface between the peripheral surface of the open bottom and the heat spreader;
introducing cooling fluid to a cooling fluid inlet positioned in the top of the housing;
directing the cooling fluid upon the heat spreader wherein the cooling fluid impinges the heat spreader in a direction substantially normal to a surface of the heat spreader wherein thermal energy is transferred from the heat spreader to the cooling fluid; and
removing the cooling fluid from the housing through a cooling fluid outlet in the housing.

12. The method as recited in claim 11, where in the heat spreader comprises a thermally-conductive thin plate.

13. The method as recited in claim 11, wherein directing the cooling fluid upon the heat spreader in a direction substantially normal to the surface of the heat spreader comprises directing the cooling fluid upon the heat spreader in a direction making a angle ranging from 85 degrees to 95 degrees with the surface of the heat spreader.

14. The method as recited in claim 11, wherein fluid sealing the interface between the peripheral surface of the open bottom and the heat spreader comprises positioning an elastomeric material in the interface.

15. The method as recited in claim 11, wherein the electronic component comprises one or more of a central processing unit (CPU), a microprocessor, a capacitor, a resistor, a memory device, and an integrated circuit. 15. A device for cooling a central processing unit (CPU) heat spreader, the device comprising:
a housing having an internal cavity, a closed top, and a polygonal open bottom, the polygonal open bottom having a peripheral surface;
an elastomeric material positioned between the peripheral surface of the open bottom and a surface of the heat spreader, the elastomeric material adapted to minimize passage of fluid between the peripheral surface of the open bottom and the surface of the heat spreader;
a single cooling fluid inlet positioned in the top of the housing, the single cooling fluid inlet adapted to direct a cooling fluid upon the surface of the microprocessor heat spreader wherein the cooling fluid impinges the heat spreader in a direction substantially normal to the surface of the heat spreader wherein thermal energy is transferred from the heat spreader to the cooling fluid; and
a cooling fluid outlet positioned to remove the cooling fluid from the housing after the thermal energy is transferred to the cooling fluid.

16. The device as recited in claim 15, where in the heat spreader comprises a thermally-conductive thin plate.

17. The device as recited in claim 15, wherein the direction substantially normal to the surface of the heat spreader comprises a direction making an angle ranging from 85 degrees to 95 degrees with the surface of the heat spreader.

18. The device as recited in claim 15, wherein the internal cavity includes an internal height of between 0.05 inches and 0.125 inches.

19. The device as recited in claim 15, wherein the device further comprises a heat exchanger having a fluid inlet operatively connected to the cooling fluid outlet and a fluid pressurizing device having an inlet operatively connected to an outlet of the heat exchanger and an outlet operatively connected to the cooling fluid inlet.

20. The device as recited in claim 15, wherein the device further comprises a mounting plate adapted to retain the housing, the mounting plate adapted to mount to a motherboard.
